(19) United States
(12) Patent Application Publication
(10) Pub. No.: US 2026/0169040 A1
(43) Pub. Date: Jun. 18, 2026

(54) PLUG-IN ENERGY MEASURING MODULE

(71) Applicant: Phoenix Contact GmbH & Co. KG, Blomberg (DE)

(72) Inventor: Martin JANKOWSKI, Seelze (DE)

(21) Appl. No.: 19/123,809

(22) PCT Filed: Oct. 26, 2023
(86) PCT No.: PCT/EP2023/079980

§ 371 Date: Apr. 24, 2025

(30) Foreign Application Priority Data
Oct. 27, 2022 (BE) BE20225875

(51) Int. Cl. G01R 22/06

(52) U.S. Cl. CPC G01R 22/065

(57) ABSTRACT

A module for measuring electrical energy includes: a housing; and a circuit carrier arranged in the housing, the circuit carrier including electronic components, plug-in slots with plug contacts being arranged on the circuit carrier. The plug-in slots with plug receive and electrically contact mating counterparts to the plug contacts arranged on an external circuit carrier. The plug contacts establish a mechanical connection between the circuit carrier of the module and the external circuit carrier upon receiving the mating counterparts to the plug contacts.

### CROSS-REFERENCE TO PRIOR APPLICATIONS

This application is a U.S. National Phase application under 35 U.S.C. § 371 of International Application No. PCT/EP2023/079980, filed on Oct. 26, 2023, and claims benefit to Belgian Patent Application No. BE 2022/5875, filed on Oct. 27, 2022. The International Application was published in German on May 2, 2024 as WO/2024/089200 under PCT Article 21(2).

### FIELD

The invention relates to a plug-in energy measuring module for capturing, displaying, and controlling at least one integrated energy quantity and a currently recorded power. Without being limited thereto, the invention particularly relates to an energy measuring module for installation in an electrical charging unit, where it can capture various electrical parameters and make them available for display and further processing. A simplified installation of the energy measuring module facilitates the assembly and maintenance of the electrical charging unit.

### BACKGROUND

Energy measuring modules are designed to capture at least parts of current, voltage, active power, and energy, which are typically the basis for billing of electrical energy. They can be implemented as a module of an electrical device to capture and forward the electrical values distributed or consumed there. Furthermore, they can be particularly protected against tampering, ensuring that the values they provide are particularly trustworthy. For this purpose, there are certifications that attest to such special trustworthiness, for example, the certificate according to Directive 2004/22/EC of Mar. 31, 2004, on measuring instruments, also referred to in technical terms as the “Measuring Instruments Directive” (MID).

The associated electrical device may be implemented as an electrical charging unit, for example, for paid charging of batteries. It may also be implemented as a switch cabinet for the distribution of electrical energy. By using certified energy measuring modules, the rest of the circuitry of the electrical device can remain uncertified without compromising the trustworthiness of the measured values. Typically, the electrical device and the energy measuring module are manufactured separately, often by different manufacturers. The attachment of the energy measuring module is usually done in DIN rail or front panel mounting housings, with wiring to the electrical device done via cables. The installation of the energy measuring module often occurs only during the assembly, configuration, or even maintenance of the electrical device.

However, considerable wiring effort is required when installing the energy measuring module. Various conductors must be integrated or routed into the power paths of the electrical devices. This often necessitates considerable cross-sections of the cables used, which are correspondingly laborious to handle. During a typical installation of the energy measuring module on construction sites, the effort increases further due to the respective local circumstances. Even for installation during manufacturing, significant installation effort is involved.

### SUMMARY

In an embodiment, the present invention provides a module for measuring electrical energy, comprising: a housing; and a circuit carrier arranged in the housing, the circuit carrier comprising electronic components, plug-in slots with plug contacts being arranged on the circuit carrier, wherein the plug-in slots with plug contacts are configured to receive and electrically contact mating counterparts to the plug contacts arranged on an external circuit carrier, and wherein the plug contacts are configured to establish a mechanical connection between the circuit carrier of the module and the external circuit carrier upon receiving the mating counterparts to the plug contacts.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 is a schematic block diagram of the module for measuring electrical energy according to a first embodiment,

FIG. 2 is a schematic block diagram of the module with a connector face according to a second embodiment,

FIG. 3 is a schematic block diagram of the module with a sealing mechanism according to a third embodiment,

FIG. 4 is a schematic block diagram of the module with electrical lines according to a fourth embodiment,

FIG. 5 is a schematic block diagram of the module with electrical couplers according to a fifth embodiment,

FIG. 6 is a schematic block diagram of the module with signaling and/or control lines according to a sixth embodiment,

FIG. 7 is a schematic block diagram of a charger according to a seventh embodiment,

FIG. 8 is a schematic block diagram of a charging station according to an eighth embodiment, and

FIGS. 9a and 9b show a perspective view of the module and the external circuit carrier with some constructive features according to a ninth embodiment.

### DETAILED DESCRIPTION

In an embodiment, the present invention provides a technique that reduces the assembly effort when installing the energy measuring module into the electrical device.

Embodiments of the invention, which may be optionally combined with one another, are disclosed below with partial reference to the figures.

A first aspect relates to a module for measuring electrical energy. The module comprises a housing and a circuit carrier (for example, a printed circuit board) arranged in the housing, equipped with electronic components. On the circuit carrier, plug-in slots with plug contacts are arranged. The plug-in slots with plug contacts can be configured as spring contacts, tongue contacts, lamella contacts, or press contacts. The plug contacts are configured to receive mating counterparts to the plug contacts. These mating counterparts to the plug contacts can be configured as connection tabs. The mating counterparts to the plug contacts can be arranged on an external circuit carrier (for example, an external printed circuit board) to establish an electrical contact upon insertion into the plug contacts (i.e., upon reception) and to establish a mechanical connection upon insertion into the plug contacts (i.e., upon reception).

In one embodiment, the plug-in slots with plug contacts can be arranged on the circuit carrier in such a number and arrangement that an operationally reliable mechanical connection (i.e., attachment) of the module is provided by the insertable or inserted mating counterparts to the plug contacts.

In further embodiments, plug-in slots with plug contacts may also be arranged on the external circuit carrier, with the corresponding mating counterparts to the plug contacts being arranged on the circuit carrier of the module.

The circuit carrier may comprise one or more printed circuit boards, with reference being made below for brevity and not limitation to a (e.g. single) printed circuit board.

The secure mechanical attachment results from the holding force of all spring contact-connection tab connections as well as from the arrangement of the spring contact-connection tab connection on the printed circuit board, i.e., the connector face. The number of spring contact-connection tab connections is not limited to the number of necessary lines between the module and the (relative to the module) external printed circuit board of the electrical device. Instead, for example, the current-carrying lines can each be divided among a plurality of spring contact-connection tab connections. This not only reduces the ohmic resistances of the spring contact-connection tab connections through parallel connection but also improves the mechanical holding forces by increasing the number of spring contact-connection tab connections. Furthermore, the distribution of the spring contact-connection tab connections can improve the mechanical connection. This can be achieved in particular by arranging at least some of the spring contact-connection tab connections along or near the outer edge of the module printed circuit board. This advantageously allows for the omission of additional fastening means for the module on the electrical device.

The mating counterparts to the plug contacts of the external printed circuit board are also known as tongue contacts. The plug contacts may be arranged within the housing of the module. By corresponding recesses in the housing of the module, the insertion of the mating counterparts to the plug contacts of the external printed circuit board (i.e., the reception) is possible for contacting the plug contacts. These recesses on the sides of the module may essentially correspond to a cross-section of the mating counterparts to the plug contacts and/or may be smaller than recesses for receiving plug contacts, which advantageously reduces susceptibility to contamination inside the module. Furthermore, damage to the particularly mechanically sensitive plug contacts of the module can be avoided by arranging the plug contacts within the housing of the module, especially during storage, assembly, or the like.

In embodiments, the module may have plug-in slots with plug contacts configured to receive rectangular, square, and/or round mating counterparts to the plug contacts. Additionally or alternatively, the plug-in slots with plug contacts of different sizes may form a connector face. Furthermore, the counterparts to the plug contacts, for example, connection tabs, may be received with recesses, wherein in the recesses mating counterparts of the plug contacts penetrate during installation of the module.

The selection and arrangement of the plug contacts with rectangular, square, and/or round mating counterparts to the plug contacts may be based on structural and/or electrical parameters, spatial conditions, required holding forces, shielding properties against electromagnetic radiation, plugging forces required for establishing or releasing the plug connections of the connectors of the connector face. Different counterparts to the plug contacts may also be used in the connector face. Advantageously, this allows taking into account the various electrical and mechanical requirements.

The connector face may be determined by the number, arrangement, different contact sizes, and/or different structural designs of the contacts. For instance, structural designs of the contacts may include plug contacts (tongue contacts), cutouts (recesses), or depressions. The associated connection tabs may include corresponding latch knobs that engage in the recess or depressions when assembling. This advantageously further increases the mechanical holding force of the plug connection.

In further embodiments, the module may arrange the plug-in slots with plug contacts on both longitudinal sides of the printed circuit board. For example, each longitudinal side may include at least 6 plug-in slots with plug contacts. Alternatively, 5 plug-in slots with plug contacts can be arranged on each longitudinal side. Further alternatively, each longitudinal side may be arranged with at least 3 plug-in slots with plug contacts. Optionally, one of the longitudinal sides may include plug-in slots with plug contacts of the same size as the plug-in slots with plug contacts on the other longitudinal side, along with additional plug-in slots with plug contacts of a smaller size.

Advantageously, 6 plug-in slots per longitudinal side can ensure sufficient electrical connection and sufficient mechanical holding force.

By arranging the plug-in slots on both longitudinal sides of the printed circuit board, space for alternative or additional fastening options for the housing can be kept free advantageously if the printed circuit board extends to the longitudinal sides of the housing. This also allows the housing openings for the plug-in slots to be arranged on both longitudinal sides of the housing. Advantageously, the underside of the housing may remain free in the middle, for example, for configuring a receptacle for a DIN rail connection, a front panel connection, or the like.

The at least 6 plug-in slots with plug contacts on both longitudinal sides of the printed circuit board or the housing of the module may be centrally arranged on at least one longitudinal side. Advantageously, the printed circuit board may only extend partially to the longitudinal side of the module.

Alternatively, the plug contacts may be arranged laterally at one end of the longitudinal side, where optionally different sized distances may be formed between the plug contacts. Furthermore, at least one of the longitudinal sides, when arranging the contacts at one end of the longitudinal side, may additionally arrange more than 6 plug-in slots with plug contacts of a smaller size at the other end of the corresponding longitudinal side. This advantageously allows for the holding force or releasing force along the longitudinal side of the module to be approximately equally distributed, making it easier to plug or unplug the module.

In other or any embodiment, the mechanical attachment of the module may be limited to the plug-in slots with plug contacts.

The electrical device into which the module for measuring electrical energy can be installed may be stationary. For example, it can be implemented as a permanently installed charger in a charging station. In such a use, no or only minimal vibrations of a base surface occur, for example, in the form of a sidewalk, a wall, a parking lot, or the like, on which the charging station is permanently mounted. Accordingly, it is sufficient for the mechanical attachment of the module in the electrical device to withstand the static forces acting on the module. This is achieved, for example, with both 6 longitudinal plug-in slots. Advantageously, this allows for the omission of additional fastening elements for the module in the electrical device, resulting in cost, handling, and space advantages.

In embodiments, a sealing device may be arranged on the module for measuring electrical energy to seal the module with the external circuit carrier. The sealing may be implemented as a mechanical sealing, for example, established with a plomb wire through the connection. Alternatively or additionally, the sealing may be implemented as a digital sealing. This can include an exchange of identifiers when initially plugging the module onto the external circuit carrier.

The mechanical sealing may include a mechanical securing of the module on the external circuit carrier in addition to the sealing with a plomb wire. Additionally, snap mechanisms or locks may be utilized. Advantageously, such locks can serve to improve the mechanical attachment of the module to the external circuit carrier.

The module and/or the electrical device may each have an identifier (for example, a number or an alphanumeric string) that allows for the identification of the individual module or the individual electrical device. The exchanged identifiers may serve as a basis for signatures or encryptions of signals output or generated by the module or the electrical device. Advantageously, this allows for the detection of an exchange of the module or the electrical device, making tampering with consumption measurement more difficult.

Furthermore, after the above exchange of the module or electrical device, the operation of the electrical device may be inhibited. Additionally, operation can only be resumed after entering a key, which re-enables the operation of the electrical device, for example, the charging station. Advantageously, this further complicates the tampering with consumption measurement.

An identifier of the module may be stored in the sealing device of the module. The exchange of identifiers may include a transmission of the identifier of the module from the sealing device through the electrical contact to an external sealing device of the external circuit carrier. Alternatively or additionally, an identifier of the external circuit carrier may be stored in the external sealing device of the external circuit carrier. The exchange of identifiers may include or involve the transmission of the identifier of the external circuit carrier from the sealing device of the external circuit carrier through the electrical contact to the scaling device of the module.

The exchange of identifiers may include or involve encrypted communication. For example, the sealing device of the module may comprise a pair of a public key and a private key, transmitting the public key to the external sealing device, receiving the identifier of or from the external sealing device encrypted with the public key, and decrypting the encrypted identifier with the private key. Alternatively or additionally, not the identifier itself is transmitted, but proof that the sealing device of the module or the external sealing device unequivocally possesses its respective identifier, for example, using a challenge-response authentication.

In further embodiments, the arrangement of the plug-in slots with plug contacts in the connector face of the module for measuring electrical energy may include information about the design (for example, a coding) of the module. Additionally or alternatively, the arrangement of the plug-in slots with plug contacts in the connector face may exclude an offset or a rotation of the module during installation onto the mating counterparts to the plug contacts of the external circuit carrier.

The information about the design of the module may indicate the type and/or function of the module, which can be considered during signaling between the external circuit carrier of the electrical device and the module. For the corresponding coding of the module identity, various mating counterparts to the plug contacts of the external circuit carrier may not find corresponding plug-in slots with plug contacts of the module. The coded design of the module may include the assignment of the plug-in slots with signals, the protocols used for signal exchange, instructions for the operation of the electrical device, or similar. Advantageously, the operating modes of the module and the external circuit carrier or the electrical device can thus be automatically coordinated.

Through the connector face, which excludes an offset or a rotation of the module during installation onto the mating counterparts to the plug contacts of the external circuit carrier, assembly errors can advantageously be prevented. These errors may include misalignment of the module on the external circuit carrier as well as the use of incompatible modules.

In other embodiments, the module for measuring electrical energy may additionally include electrical lines, which are coupled or coupleable to the external circuit carrier. The coupled or coupleable lines may be electrically conductively connected or connectable to the module.

Thus, measuring currents do not need to flow through the plug-in slots, for example, to avoid the resulting resistances in the connection. Accordingly, cables to be sealed, if necessary, may be installed between the external circuit carrier and the module. Although this arrangement presents an obstacle to the replacement of the module, this cabling is limited to a few cables (lines), for example, to 3 lines, so that an advantageously simplified assembly or replacement is achieved as compared to complete wiring and sealing.

In embodiments, the module for measuring electrical energy may include couplers for measuring currents in the electrical lines without electrical contact with the lines.

Instead, lines with measuring currents can be captured through transformers in the module for galvanically isolated measurement of the measuring currents. Advantageously, this can avoid the insertion of additional resistances in the measuring currents without significant impairment of the measurement accuracy.

In further embodiments, the module for measuring electrical energy may include additional electrical lines of the module as signaling and/or control lines. These may optionally be used to control a display (or an indicator) not arranged on the printed circuit board and/or to electrically connect at least one operating element not arranged on the printed circuit board. Here, the display and/or the operating element may be visible or operable with the housing of the electrical device closed.

These signaling and/or control lines may at least partially be connected to the external circuit carrier, for example, in the case that the display and/or the operating element are electrically connected with the module's printed circuit board via the external circuit carrier, and the display and/or the operating element are readable or operable outside the electrical device. These signaling and/or control lines may also be connected via plug contacts (for example, at the plug-in slots) with the external circuit carrier. Advantageously, information from the module can thus be output via the electrical device to an operator. Furthermore, the operator may control the module through the electrical device.

In other embodiments, the module for measuring electrical energy may include at least one plug-in slot with plug contacts for the operation of serial interfaces, which may optionally be configured as Ethernet and/or RS485 and/or for operation as digital inputs and outputs.

These serial interfaces may serve to control the module. For example, the module may be placed in predetermined operating states, which may include, for example, enabling or locking (or blocking) the module, exchanging identifiers, or similar. Alternatively or additionally, they may serve to output signals from the module in the form of digital inputs and outputs. These output signals may include measured values captured by the module. By using standardized interfaces, adaptation of the external circuit carrier and the electrical device to the module properties or of the module to the external circuit carrier and the electrical device can be advantageously simplified. Furthermore, the use of serial interfaces may save plug-in slots.

In embodiments, at least one plug-in slot with plug contacts on the module for measuring electrical energy may be configured to transmit the current to be measured and/or the voltage to be measured.

In the case of higher currents, multiple parallel-connected plug-in slots with plug contacts may transmit the current to be measured. The number of parallel-connected plug-in slots with plug contacts and their electrical properties are chosen so that unwanted interference with the current to be measured and/or the voltage to be measured is avoided. Advantageously, this can prevent unwanted interference with the measurement values while maintaining the simpler installation option without wiring effort.

In further embodiments, the module for measuring electrical energy may be MID-compliant with the MID (“Measuring Instruments Directive”). Furthermore, the module may conform to another or several further certificates for trustworthy billing. Additionally or alternatively, it may include or control a pulse LED that outputs pulses proportional to the delivered power.

The Measuring Instruments Directive 2014/32/EU, MID, is a directive of the European Union that aims to harmonize many aspects of legal metrology in all EU member states. It mandates, among other things, that at least one integrated amount of energy (kWh on the display) as well as the current power (kW according to pulse LED) are verifiable from the outside. The MID testing of the module is conducted independently of its later use. With MID compliance, the module is also certified with increased tamper resistance. Accordingly, many operators of corresponding electrical devices, for example, an electrical device in a vehicle charging station, require such a certification. Advantageously, this can achieve increased protection against tampering.

In other embodiments or according to a second aspect, a charger for a vehicle may incorporate the module for measuring electrical energy and the external circuit carrier. Here, the external circuit carrier additionally includes a charging controller and (for example, all) power components for charging the vehicle.

The charger for charging the vehicle may be provided as a complete module, suitable for a wide range of end products, and accordingly includes all relevant charging functions. Advantageously, such an end product, for example, a charging station or wallbox, can integrate a charging function for charging a vehicle without having to provide additional related functionality. The charger may be an embodiment of the electrical device.

For brevity and without limiting it to a charging station, reference will be made, where applicable, to a wallbox.

In each aspect, the module may be configured to transmit signals signed if the operating or user display is electrically indirectly connected with the module or if (or when) the operating or user display is not arranged on the module's circuit carrier. Alternatively or additionally, the module may be configured to transmit the electrical signals between the module and the built-in operating or user display unsigned if the operating or user display is electrically directly connected with the module or if the operating or user display is arranged on the module's circuit carrier.

In embodiments or according to a third aspect, a charging station for electrically charging a vehicle can include the charger. The charging station includes a built-in operating or user display, where the operating or user display may optionally be configured to be touch-sensitive.

The operating or user display may include the functionality of the MID. Thus, the user display may show the integrated amount of energy (kWh) as well as the current power (kW according to pulse LED). Furthermore, the user display may include the operating element of the module. Advantageously, the charging station can thus contribute to MID compliance.

In some embodiments, the charging station transmits electrical signals between the module and the built-in operating or user display in a signed manner when the built-in operating or user display, built into the charging station, is electrically indirectly connected to the module. Optionally, the signing is based on at least one of the exchanged identifiers. Alternatively, electrical signals are transmitted unsigned between the module and the built-in operating or user display if the operating or user display is electrically directly connected with the module,

The indirect electrical connection between the module and the built-in operating or user display can be conducted, for example, via the external circuit carrier of the electrical device. Additionally, it may be transmitted from the electrical device to the charging station. Alternatively, the built-in operating or user display contained in the charging station may also be built into the electrical device, which is arranged in the charging station so that it can be operated by an operator. In these cases, a signature may be added to the signals to be transmitted. Additionally or alternatively, the signals to be transmitted may be encrypted. The encryption may optionally be based on the exchanged identifiers of the module and the electrical device, Advantageously, tampering with the signals or unauthorized tapping of the signals can be hindered.

In some embodiments, the charging station may prevent charging with the charging station after changing at least one of the identifiers of the module and the external circuit carrier. Optionally, a renewed exchange of identifiers is only possible after entering a key for renewed digital sealing of the module and the external circuit carrier.

Changing at least one of the identifiers of the module and the external circuit carrier can be initiated by the operator of the charging station. Special security mechanisms may be used, which may include mutual authentication and may rely on secret keys, which differ from the mentioned key. Additionally, the entry of the key for a renewed exchange of identifiers may be initiated by the operator, again using the special security mechanisms.

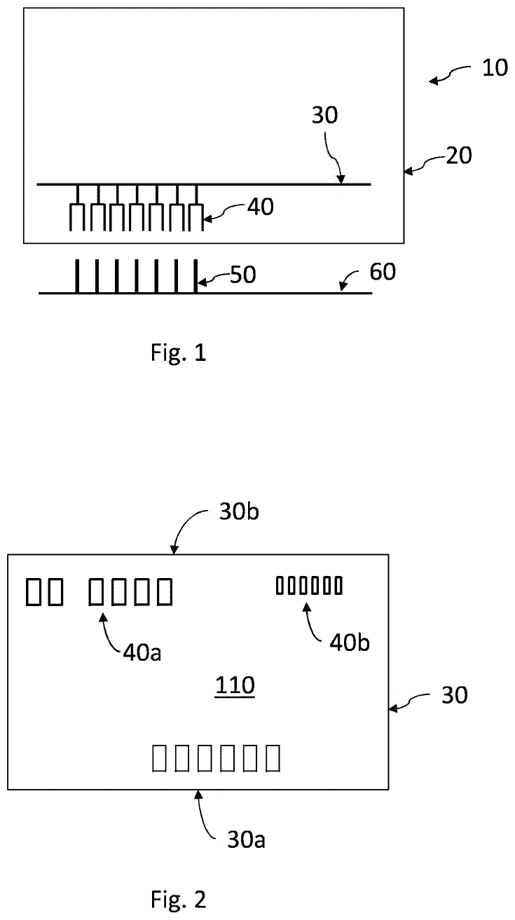

FIG. 1 shows a schematic block diagram of the module 10 for measuring electrical energy. The module comprises a housing 20 and a circuit carrier (or printed circuit board) 30 arranged within the housing with electronic components. On the circuit carrier, plug-in slots 40 with plug contacts are arranged, which are located within the housing 20. The reference sign 40 of the plug-in slot is also used for the respective plug contact. The plug-in slots 40 with plug contacts are configured to receive mating counterparts to the plug contacts 50, which are arranged on an external printed circuit board 60, with which an electrical contact is established upon insertion into the plug contacts, and with which a mechanical connection is established upon insertion into the plug contacts.

For this purpose, recesses are arranged in the housing 20 so that the mating counterparts to the plug contacts 50 can contact the plug contacts 40. The plug-in slots with plug contacts are arranged on the printed circuit board in such a number and arrangement that a secure mechanical attachment of the module is provided by the insertable mating counterparts to the plug contacts. For clarity, the external printed circuit board 60 with the mating counterparts to the plug contacts 50 is shown in the non-contacted state with respect to the module 10.

FIG. 2 shows a schematic block diagram of the circuit carrier (or printed circuit board) 30 with a connector face 110, wherein the connector face is formed by the plug contacts 40. The plug-in slots with plug contacts 40 are configured on the printed circuit board 30 to receive rectangular, square, and/or round mating counterparts to the plug contacts. Additionally or alternatively, the plug-in slots with plug contacts 40 of different sizes may form the connector face 110, with plug-in slots with large plug contacts 40a and plug-in slots with small plug contacts 40b shown. Further complementarily or alternatively, the mating counterparts to the plug contacts can be received in recesses of the housing 20, with mating counterparts of the plug contacts penetrating into the recesses during installation of the module.

The module further shows the arrangement of the plug-in slots with plug contacts 40a, 40b on both longitudinal sides 30a, 30b of the printed circuit board 30. Each longitudinal side 30a and 30b includes 6 plug-in slots with large plug contacts 40a. On the upper longitudinal side 30b, the plug-in slots with plug contacts include those in the size of the plug-in slots with plug contacts 40a of the lower longitudinal side 30a and additionally those plug-in slots with plug contacts of a smaller size 40b. On the upper longitudinal side 30b, the larger plug contacts 40a are arranged at the left end of the longitudinal side 30b at equal distances from each other, with the exception that after the two outer slots, there is a larger gap to the next slot. At the right end of the longitudinal side 30b, the smaller plug contacts 40b are again arranged at equal distances from each other, with the distances being smaller than for the larger plug contacts 40a. On the lower longitudinal side 30a of the printed circuit board 30, the 6 plug-in slots with large plug contacts 40a are arranged centrally at equal distances from each other.

In the housing 20, through the arrangement of the plug contacts 40a, 40b on the longitudinal sides 30a, 30b, the housing underside between the plug contacts can be used for alternative or supplementary fastening elements, for example, for configuring a receptacle for a DIN rail connection, a front panel connection, or the like.

Alternatively, the mechanical attachment of the module may be limited to the plug-in slots with the plug contacts. Through the arrangement and design of the plug contacts shown here, sufficient holding force for the module is generated solely by the large plug contacts 40a alone, e.g. at least in the case of a fixed installation of the electrical device with the external printed circuit board.

Additionally, the arrangement of the plug-in slots with the plug contacts 40a, 40b in the connector face includes information about the design of the module. Accordingly, the installation of an incompatible module is hindered or not possible. Furthermore, coding of the module through leaving out mating counterparts to the plug contacts 50 of the external printed circuit board 60 is possible. Additionally, the arrangement of the plug-in slots with plug contacts in the connector face excludes an offset or rotation of the module during installation on the mating counterparts to the plug contacts of the external printed circuit board.

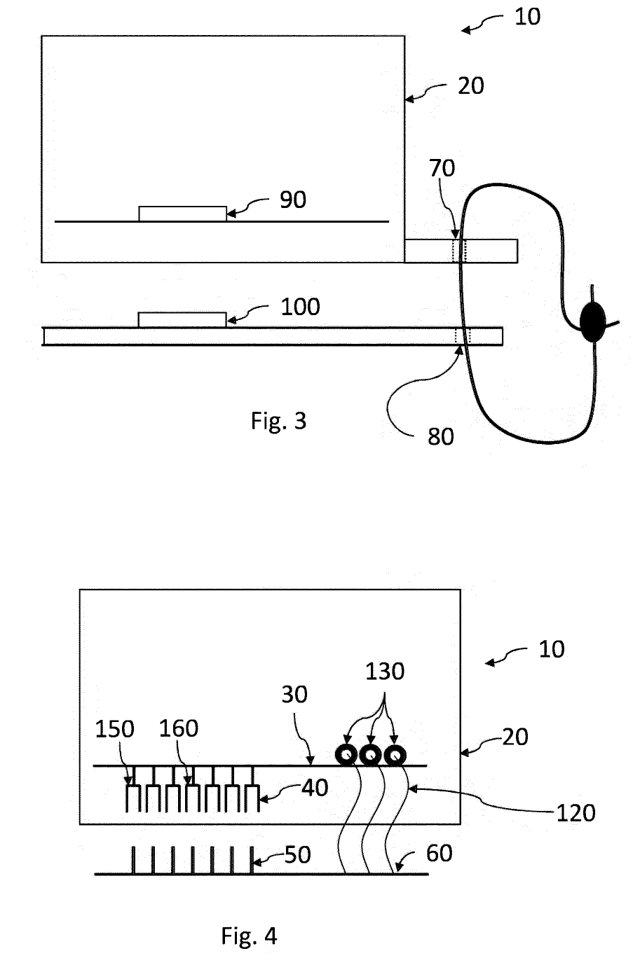

FIG. 3 shows a schematic block representation of the module 10 with a mechanical sealing 70, 80. For this purpose, the housing 20 includes a separate sealing bar 70, which is flanged to a side wall. This sealing bar 70 includes a hole for the sealing wire. Correspondingly, at least one sealing hole 80 is located in the external printed circuit board 60 for passing the sealing wire. The sealing wire passed through the holes of the module 10 and the external printed circuit board 60 is fixed by a seal.

Alternatively or additionally, the sealing is implemented as digital sealing. For this purpose, information for digital sealing is stored in a memory 90 in the module. Corresponding information is stored in a memory 100 of the external printed circuit board. The sealing can be based on an exchange of an identifier of the module and an identifier of the external printed circuit board. If the received identifier does not match the expected identifier, the operation of the module can be terminated or disabled. These identifiers can be particularly protected against changes, for example, by a preceding authentication. The own identifier of the module may be stored in memory 90. The own identifier of the external circuit carrier may be stored in memory

FIG. 4 shows the module 10 for measuring electrical energy with at least three electrical lines 120 in addition to the plug-in slots with plug contacts 40, which the mating counterparts to the plug contacts 50 of the external printed circuit board 60 face. Each of the at least three lines 120 is routed through a current sensor 35 arranged on the printed circuit board 30 of the module 10. The current sensors 35 are galvanically isolated (contactless) from the lines 120 and determine the respective current strength based on the magnetic flux density induced by electrical currents. These three lines 120 lead to the external printed circuit board and are electrically conductively connected to it. They carry the current to be measured according to the three-phase power phases, each offset by 120°.

The module 10 includes on its printed circuit board 30 at least one plug-in slot with plug contacts for the operation of serial interfaces 150, which may be configured as Ethernet and/or RS485 and/or for operation as digital inputs and outputs. These may include data for parameterization as well as measurement results. Advantageously, this may save plug-in slots through the serial interface.

For example, the measurement results (partially or completely, and/or periodically, event-driven, or on request) may be transmitted via the serial interface 150 to a higher-level and/or outside the module 10 charging station control. The higher-level control may serve as a control for multiple adjacent charging parking spaces.

For the module 10, at least one plug-in slot with plug contacts 160 is configured to transmit the current to be measured and/or the voltage to be measured. Alternatively, only the voltage to be measured may be transmitted over the plug contacts 160 in addition to the current transmission through the lines 120. Further alternatively, the lines 120 may be omitted, and both the current and voltage may be transmitted via a plurality of plug contacts 160.

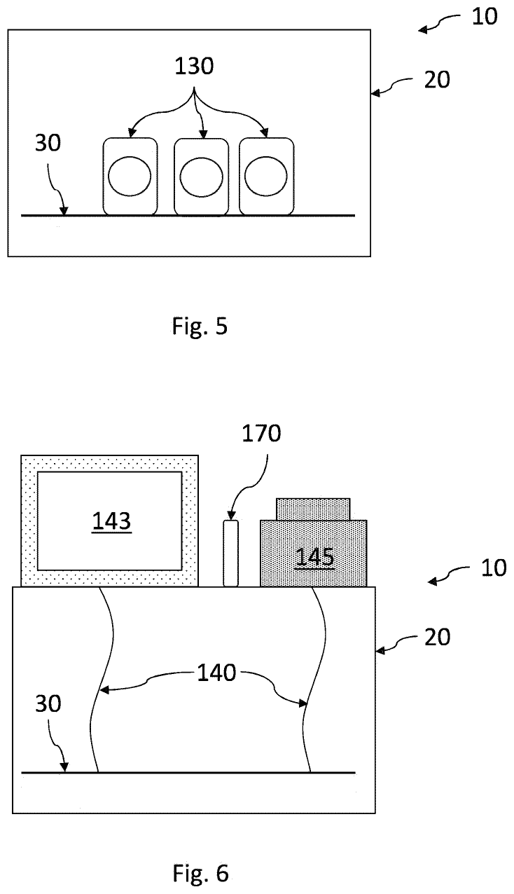

FIG. 5 shows the module 10 for measuring electrical energy, which includes a coupler 130 for current measurement in the electrical lines without electrical contact with the lines. The couplers 130 are implemented as (for example, inductive) measuring transformers. The couplers 130 are arranged on the printed circuit board 30. Alternatively, the couplers may also be arranged elsewhere in the module, for example, on an auxiliary printed circuit board or mounted on the housing 20.

FIG. 6 shows a schematic block representation of the module 10. The module 10 for measuring electrical energy includes signaling and/or control lines 140. These are electrically conductively connected to the printed circuit board 30. Optionally, they may also be separately electrically connected, for example, to an auxiliary printed circuit board. They serve to control a display 143 not arranged on the printed circuit board 30 and for electrical connection of at least one operating element 145 not arranged on the printed circuit board. Here, the display 143 and the operating element 145 are visible or operable with the housing 20 of the module 10 closed. Alternatively, only the display 143 or only the operating element 145 may be present. Further alternatively, the display 143 and the operating element 145 may also be visible or operable with the housing of the electrical device closed. Additionally alternatively, the signaling and/or control lines 140 may also be routed through the external printed circuit board 60 of the electrical device.

Furthermore, the module 10 is MID (Measuring Instruments Directive) compliant. Accordingly, at least one integrated amount of energy (kWh) is displayed on the display 143 as well as the current power (kW) is indicated via a pulse LED 170 that outputs pulses proportional to the delivered power. The pulse LED 170 and the display 143 are verifiable from the outside by an operator of the electrical device. The display 143, the operating element 145, and the pulse LED 170 are components of the module. Alternatively, they may also be controlled as separate components by the module.

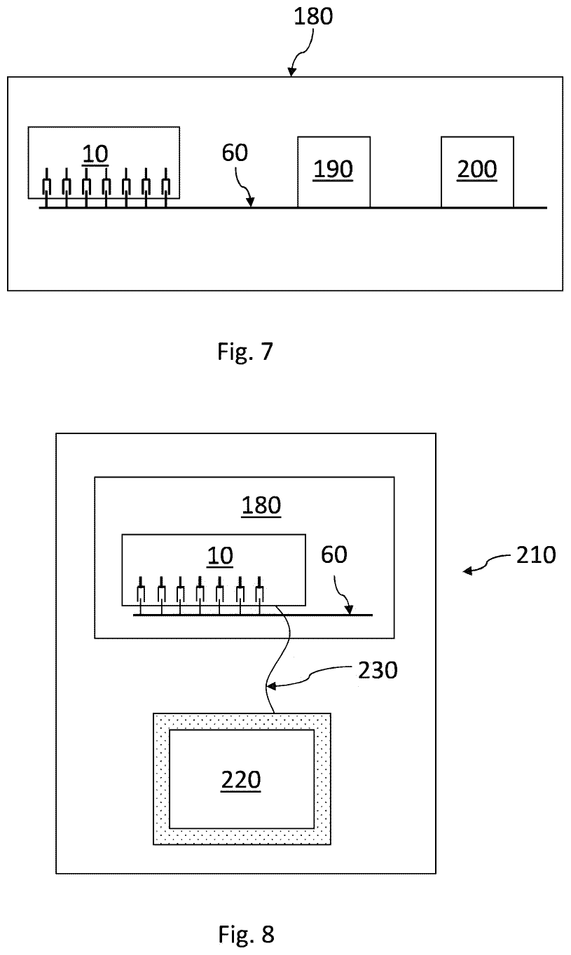

FIG. 7 shows a schematic block representation of a charger 180 for a vehicle. This includes the module 10 for measuring electrical energy and the external printed circuit board 60, whose plug contacts or mating counterparts to the plug contacts are also shown. The external printed circuit board 60 additionally includes a charging controller 190 and all power components 200 for charging a vehicle. The charger 180 is intended for installation in a station and includes all necessary mechanical and electrical connections for this purpose.

FIG. 8 shows a schematic block representation of a charging station 210. This serves for the electrical charging of a vehicle. It includes a built-in operating or user display 220 and the charger 180, where the operating or user display 220 is optionally configured to be touch-sensitive. Alternatively, a user guide or interaction can also be carried out separately via corresponding buttons 154. Further alternatively, the operating or user display 220 can be provided by the module 10, the charger 180, or the charging station 210 itself. All elements (operating or user display 220, possibly buttons 154, and possibly pulse LED 170) are recognizable or operable by the operator. Thus, the prerequisites for MID compliance are given.

In the charging station 210, electrical signals 230 are transmitted between the module 10 and the built-in operating or user display 220 signed if the operating or user display 220 built into the charging station 210 is electrically indirectly connected to the module 10. This may be the case if or when the electrical signals 230 are routed through the external printed circuit board 60. The signing is based on at least one of the exchanged identifiers. Alternatively, electrical signals 230 are transmitted unsigned between the module and the built-in operating or user display if or when the operating or user display 220 is electrically directly connected with or to the module 10 and thus the operating or user display 220 is an element of the module 10.

Furthermore, the charging station 210 prevents charging with the charging station 210 after changing at least one of the identifiers of the module 10 and the external printed circuit board 60. Optionally, a renewed exchange of identifiers between the module 10 and the external printed circuit board 60 is only possible after entering a key for renewed digital sealing of module 10 and external printed circuit board 60.

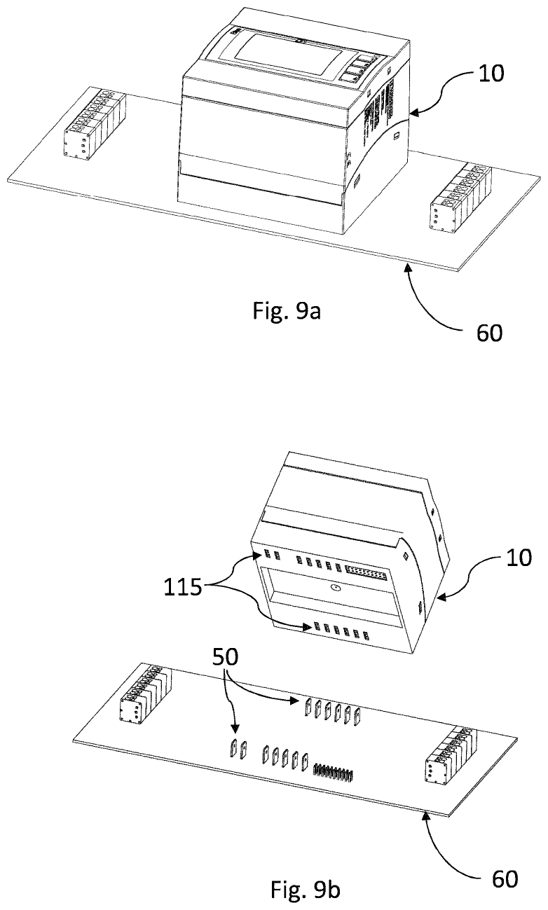

FIGS. 9a and 9b show the module 10 and the external printed circuit board 60 with some constructive features. FIG. 9a shows an assembled state of module 10 and external printed circuit board 60. FIG. 9b shows an unassembled state of module 10 and external printed circuit board 60. The bottom surface of the module 10 reveals the recesses 115 in the housing 20 of the module 10 for the insertion of or receiving the mating counterparts to the plug contacts of the external printed circuit board 60. The associated or corresponding mating counterparts to the plug contacts 50 are recognizable on the external printed circuit board 60. Additionally, clamping or terminal elements for wiring are shown on the external printed circuit board 60.

In other words, the invention can be described as follows: Measuring devices in various forms and configurations are known. Specifically, the known multifunctional energy measuring devices are usually housed in DIN rail or front panel mounting housings or enclosures. In applications, the known measuring devices are then also used in this way. The measuring devices are connected via cables in the power path that supplies the application with current and voltage. Likewise, all interfaces are connected via cables.

In inventive applications, the wiring effort can be avoided if the measuring device (module 10) can be plugged onto an existing carrier printed circuit board (external printed circuit board 60 of the electrical device). This can be applicable, for example, in the charging infrastructure for electromobility. Here, the charging controllers are usually housed on printed circuit boards (external printed circuit board 60) in a housing. This printed circuit board with the charging controller (external printed circuit board 60) also contains all power components (power components of the charger 200) for vehicle charging. In addition to the charge control, an energy measuring device (module 10) can additionally be plugged in. In particular, this is a measuring device (module 10) compliant with the respective local calibration law requirements. The measuring device (module 10) can obtain the locally required calibration law compliance for itself and can thus be qualified independently of the application.

The wiring effort is completely eliminated by simply plugging the measuring device (module 10) onto the existing carrier printed circuit board (external printed circuit board 60). The plug contacts (plug-in slots with plug contacts 40) contain the power components necessary for the full implementation or complete capture of the measuring functions. In other words, the charging current and the charging voltage as components of the electrical power P=U*I are present at the plug contacts or flow over the plug contacts to and from module 10. This applies particularly to a three-phase network or grid connection, allowing measurement of the energy consumption of a downstream consumer. Alternatively, the measuring current can be conducted not through the printed circuit board 30, but through measuring transformers 130.

The measuring device (i.e., module 10) can be a multifunctional measuring device that contains individual or all features or functions known for measuring devices, such as current and voltage measurement, power and energy measurement for active, reactive, and apparent power and/or energy.

The measuring device can be, in particular, MID-compliant. The measuring device can include a display 143 and operating elements 145. Furthermore, the measuring device can include a pulse LED 170 that outputs pulses proportional to the delivered or measured power.

The measuring device may include interfaces that can also be guided via plug contacts (plug-in slots with plug contacts 40) onto the carrier printed circuit board (external printed circuit board 60). This may include particularly serial interfaces 150 but also digital inputs and outputs 150. The serial interfaces 150 may include Ethernet or RS485. Via these interfaces, a higher-level charge control can communicate with the measuring device (i.e., the module 10). For example, billing-relevant data, such as the energy delivered for charging, can be transmitted. This can also occur in a secure mode in which the measurement data, for example, is signed. The measuring device can be secured against unauthorized removal or manipulation through a suitable mechanical arrangement. This may be, for example, a mechanical lock or locking mechanism that can be sealed with suitable means.

The measuring device (module 10) can be powered by or from the measuring voltage and/or supplied by an auxiliary voltage, so the measuring device can also be connected between a switch and a consumer in the power path.

In a charging station 210, a charge control 190 is integrated on a printed circuit board 60. If the respective energy consumption of the vehicle to be charged is to be captured, an MID-compliant energy meter (i.e., the module 10) is usually additionally installed in the housing. This means additional wiring effort in the state of the art. In contrast, the energy meter according to one embodiment of the invention can be plugged in as described, significantly reducing the effort.

The plug-in assembly (i.e., an embodiment of the module 10) offers, in addition to this function, the possibility of communicating with the electronics of the charging station 210. This communication can take place, for example, via a serial interface 150.

For use as a charging station 210, the information of the energy quantity per charging process is relevant. This information can be optionally encrypted exchanged between the charging station 210 and the measuring device (i.e., the module 10). The measuring device can include an additional function that reports back the energy quantity for the current charge marked by signals from the charging station.

The connector face of the measuring device (I.e., the connector face of module 110) is designed so that an accidental incorrect installation is not possible. For this purpose, the plug connections (plug-in slots with plug contacts 40) are arranged so that an offset or rotation of the measuring device is not possible.

During the initial installation, the measuring device (i.e., module 10) and the charging station 210 can exchange and store identifiers that allow for recognizing a change of devices mutually. The charging station 210 can access all relevant measurement results of the measuring device to assess the condition and load of the entire charging string. To ensure the MID compliance of the measuring device (i.e., the module 10) in the charging station 210, it is required that the display 143 and the pulse LED 170 are visible from the outside. For this purpose, the display 143 and/or the pulse LED 170 is implemented as a detached unit.

In addition to the indicator (e.g., display 143), operating elements 145 for the measuring device may also be accessible from the outside.

As an additional function, for example, the fault current may be captured if or recorded when the neutral conductor current is also captured or measured. This may also be implemented as an additional measuring module (i.e., as another embodiment of the module 10).

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE SIGN LIST

10 Module for measuring electrical energy
20 Housing of the Module
30 Circuit carrier, for example, printed circuit board, of the module
30a Longitudinal side of the circuit carrier
30b Other longitudinal side of the circuit carrier
40 Plug-in slots with plug contacts
40a Plug-in slots with large plug contacts
40b Plug-in slots with small plug contacts
50 Mating counterparts to the plug contacts of the external circuit carrier
60 External circuit carrier, for example, printed circuit board, of the electrical device
70 Mechanical sealing device of the module
80 Mechanical sealing device of the external circuit carrier
90 Memory with digital sealing in the module
100 Memory with digital sealing of the external circuit carrier
110 Connector face of the module
115 Recesses of the housing for receiving the mating counterparts to the plug contacts
120 Electrical lines from the module to the external circuit carrier
130 Coupler for measuring currents in the electrical lines without electrical contact
140 Signaling and/or control lines of the module
143 Display, for example, display
145 Operating Element
150 Plug-in slot with spring contact for the operation of serial interfaces
160 Plug-in slot with spring contact for transmitting the current to be measured and/or the voltage to be measured
170 Pulse LED of the module
180 Charger for a vehicle
190 Charging control, also: charging controller, of the charger
200 Power components of the charger
210 Charging station
220 User display, built into the charging station
230 Signed or unsigned electrical signals

1. A module for measuring electrical energy, comprising:
a housing; and
a circuit carrier arranged in the housing, the circuit carrier comprising electronic components, plug-in slots with plug contacts being arranged on the circuit carrier,
wherein the plug-in slots with plug contacts are configured to receive and electrically contact mating counterparts to the plug contacts arranged on an external circuit carrier, and
wherein the plug contacts are configured to establish a mechanical connection between the circuit carrier of the module and the external circuit carrier upon receiving the mating counterparts to the plug contacts.

2. The module for measuring electrical energy of claim 1, wherein a number and arrangement of the plug-in slots with plug contacts on the circuit carrier is configured to mechanically connect the module to the external circuit carrier in an operationally reliable manner via the receivable mating counterparts to the plug contacts.

3. The module for measuring electrical energy of claim 1, wherein the plug-in slots with plug contacts are configured to receive rectangular, square, and/or round mating counterparts to the plug contacts, and/or
wherein the plug-in slots with plug contacts of different sizes form a connector face, and/or
wherein the mating counterparts to the plug contacts are received or receivable with recesses, and wherein mating counterparts of the plug contacts are configured to penetrate into the recesses upon receiving the mating counterparts to the plug contacts and/or during installation of the module.

4. The module for measuring electrical energy of claim 1, wherein the plug-in slots with plug contacts are arranged on both longitudinal sides of the circuit carrier.

5. The module for measuring electrical energy of claim 1, wherein the mechanical connection or a mechanical fastening of the module is limited to the plug-in slots with plug contacts.

6. The module for measuring electrical energy of claim 1, further comprising:
a sealing device configured to seal the module with the external circuit carrier.

7. The module for measuring electrical energy of claim 1, wherein the arrangement of the plug-in slots with plug contacts in the connector face includes information about the configuration, function, or limits of the module, and/or
wherein the arrangement of the plug-in slots with plug contacts in the connector face excludes an offset or rotation of the module upon receiving the mating counterparts to the plug contacts and/or installation of the module on the mating counterparts to the plug contacts of the external circuit carrier.

8. The module for measuring electrical energy of claim 1, further comprising:
electrical lines which are coupled or coupleable to the external circuit carrier.

9. The module for measuring electrical energy of claim 8, wherein further electrical lines of the module include signaling and/or control lines which are configured to control a display not arranged on the circuit carrier and/or to electrically connect at least one operating element not arranged on the circuit carrier with the circuit carrier, and
wherein the display and/or the operating element are visible or operable with the housing of the module and/or an electrical device receiving the module closed.

10. The module for measuring electrical energy of claim 1, wherein at least one plug-in slot with plug contacts is configured for the operation of serial interfaces.

11. The module for measuring electrical energy of claim 1, wherein at least one plug-in slot with plug contacts is configured to transmit a current to be measured and/or a voltage to be measured from the external circuit carrier to the circuit carrier of the module.

12. The module for measuring electrical energy of claim 1, wherein the module is MID-compliant and/or compliant of a further certificate for trustworthy billing and/or includes or controls an optical interface configured to output pulses at a rate proportional to the measured power.

13. A charger for a vehicle, comprising:
the module for measuring electrical energy of claim 1; and
the external circuit carrier, the external circuit carrier including a charging controller and power components configured to charge the vehicle.

14. A charging station or wallbox for electrically charging a vehicle, comprising:
the charger of claim 13; and
built-in operating or user display.

15. The charging station or wallbox of claim 14,
wherein electrical signals between the module and the built-in operating or user display in the charging station or the wallbox are transmittable in a signed manner.

16. : The charging station or wallbox of claim 14, the charging station or wallbox being configured to prevent charging with the charging station after changing at least one of the identifiers of the module and the external circuit carrier.

17. The module for measuring electrical energy of claim 3, wherein the connector face comprises an asymmetric connector face.

18. The module for measuring electrical energy of claim 4, wherein each longitudinal side comprises 3, 5, or 6 plug-in slots with plug contacts, and/or
wherein on one of the longitudinal sides, the plug-in slots include plug contacts in a size of the plug-in slots with plug contacts of an other longitudinal side and additionally plug-in slots with plug contacts of a smaller size.

19. The module for measuring electrical energy of claim 5, wherein the plug contacts comprise spring contacts, lamella contacts, or press contacts.

20. The module for measuring electrical energy of claim 6, wherein the sealing comprises mechanical sealing, and/or
wherein the sealing comprises digital sealing and includes an exchange of identifiers upon initially plugging the module onto the external circuit carrier.
